(19) United States
(12) Patent Application Publication
(10) Pub. No.: US 2006/0270165 A1
(43) Pub. Date: Nov. 30, 2006

(54) Multi-layered spacer for lightly-doped drain MOSFETS

(75) Inventors: Kyeonglan Rho, Maple Grove, MN (US); Noel Hoilien, Saint Paul, MN (US); Daniel Fertig, Edina, MN (US); Steven Kosier, Lakeville, MN (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Polar Semiconductor, Inc., Bloomington, MN (US)

(21) Appl. No.: 11/436,879

(22) Filed: May 18, 2006

Related U.S. Application Data
(60) Provisional application No. 60/682,447, filed on May 19, 2005.

(51) Int. Cl. H01L 21/336; H01L 29/76

(52) U.S. Cl. 438/286; 257/288

(57) ABSTRACT

A spacer for a lightly-doped drain MOSFET includes a first spacer layer adjacent to and in contact with a gate region and a lightly-doped region, a second spacer layer adjacent to and in contact with the first layer and a third spacer layer adjacent to and in contact with the second layer.

### CROSS-REFERENCE TO RELATED APPLICATION(S)

The present invention claims priority from U.S. Provisional Application No. 60/682,447, filed May 19, 2005 for “Silicon Dioxide and Silicon Nitride Layered Metal-Oxide-Semiconductor Field Effect Transistor Spacer for Intergration of a High Quality Anti-Reflective Coating into an Integrated Circuit Process” by K. Rho, N. Hoilien, D. Fertig and S. Kosier.

### INCORPORATION BY REFERENCE

The aforementioned Provisional Application No. 60/682,447 is hereby incorporated by reference in its entirety.

### BACKGROUND OF THE INVENTION

A metal oxide semiconductor field effect transistor (MOSFET) is a four-terminal device that can, when properly biased, controllably vary the magnitude of a current that flows between two of the terminals. The four terminals include a body terminal, a gate terminal, a source terminal and a drain terminal. As its name implies, the MOSFET is made a layer of metal separated from a semiconductor by a layer of oxide. The gate terminal was originally made of metal but now is typically made of polysilicon, while the body, source and drain terminals are doped semiconductors. The majority charge carriers of the source and drain are of the opposite type than the majority charge carriers of the body.

A field effect that depends on the voltage applied to each of the MOSFET terminals takes place at the surface of the body, resulting in either an accumulation of body majority charge carriers, depletion of body majority charge carriers and/or formation of a layer of charge carriers (“channel”) that are of the opposite type of the body and supplied by the source. To first order, when the MOSFET is in accumulation or depletion, it is considered to be “off”, since current cannot flow between the source and drain. In inversion, the MOSFET is considered to be “on”, since current can flow through the channel when a voltage is applied between the source and drain.

Reducing the size of transistors is often desirable. However, at short channel lengths, the electric field on the drain side of the channel grows. As this electric field increases, electron-hole pairs can be generated by impact ionization. Some of the electrons generated in the space charge region are attracted to the oxide due to the electric field induced by a positive gate voltage. These generated electrons have far higher energies than the thermal-equilibrium value and are thus referred to as “hot carriers”. These hot carriers may be able to tunnel into the oxide, or, in some cases, may be able to overcome the silicon oxide potential barrier and produce a gate current. Also, some of the electrons traveling through the oxide may become trapped, producing a net negative charge density in the oxide. The hot electron effects are a continuous process, and the device performance degrades as the number of carriers trapped in the oxide above the drain increases. Obviously, this hot carrier induced (HCI) degradation is an undesirable effect and will reduce the useful lifetime of the device.

One approach to reduce these HCI effects is to alter the doping profile of the drain. By introducing a lightly doped region between the source and the channel and between the drain and the channel, the peak electric field on the drain side of the channel is reduced. To create a MOSFET with lightly doped regions, a polysilicon gate is formed over the gate oxide. Then, the lightly-doped drain (LDD) is implanted into the body everywhere except where it is blocked by the polysilicon gate. A layer of insulating material, such as silicon dioxide or silicon nitride, is then deposited on the gate polysilicon and residual gate oxide and anisotropically etched to form a spacer around the gate. The spacer and gate polysilicon block the subsequent heavier doping of the source/drain implant. This process results in a lightly doped “finger” under the gate is called a lightly-doped drain (LDD) extension.

Furthermore, transistors such as LDD MOSFETs are commonly used in optical read systems. In order to improve the sensitivity of the optical read system, an anti-reflective coating (ARC) is used. The ARC allows the appropriate wavelengths of light to be transmitted through the coating with maximum transmission and minimum reflection. To minimize process complexity, ARCs are typically formed as one of the final steps in the manufacture of optical read integrated circuits. However, the presence of metal interconnects with a low melting point at the end of the process limits the ARC formation temperature and therefore limits the quality of the ARC. To achieve a high quality ARC, it must be formed before metal interconnect. However, if the ARC is formed before metal interconnect, either additional process steps must be added to remove the ARC from all devices except those that specifically require the ARC (such as photodiodes) or the ARC layers must be incorporated into devices that do not specifically require the ARC (such as MOSFETs).

Thus, there is a need in the art for MOSFETs that experience reduced hot carrier degradation. There is also a need in the art for MOSFETs that can be fabricated in conjunction with an anti-reflective coating for use in optical systems. However, these improvements should not come at the expense of reduced performance or increased fabrication expense.

### BRIEF SUMMARY OF THE INVENTION

The invention is a multi-layered spacer used in a lightly-doped drain MOSFET. A MOSFET incorporating the multi-layered spacer exhibits reduced hot carrier degradation compared to a silicon dioxide-only spacer, resulting in a longer useful life of the device. This improvement is achieved without significantly changing the other electrical parameters of the device. The multi-layered structure allows for improved end-point detection in the etching required for any MOSFET spacer. Finally, the multi-layered spacer also provides for simplified application of anti-reflective coating to the circuit, which provides improved utility in applications such as photodiodes and optical read systems.

### BRIEF DESCRIPTION OF THE DRAWINGS

FIG. 1 is a cross-sectional view of a MOSFET gate and spacer according to one embodiment of the invention.

FIG. 2 is a cross-sectional view of a MOSFET including a spacer according to one embodiment of the invention.

FIG. 3A is a cross-sectional view of a MOSFET gate and spacer as known in the prior art.

FIG. 3B is a cross-sectional view of another MOSFET gate and spacer as known in the prior art.

FIG. 3C is a cross-sectional view of a bipolar junction transistor with a layered spacer between the emitter and base as known in the prior art.

FIG. 4 is a graph showing the reduced hot carrier degradation of the invention and comparing it to MOSFETs using conventional spacers.

While the above-identified figures set forth embodiments of the invention, other embodiments are also contemplated, as noted in the discussion. In all cases, this disclosure presents the invention by way of representation, and not limitation. It should be understood that numerous other modifications and embodiments that fall within the scope and spirit of the principles of this invention can be devised by those skilled in the art. The figures may not be drawn to scale.

### DETAILED DESCRIPTION

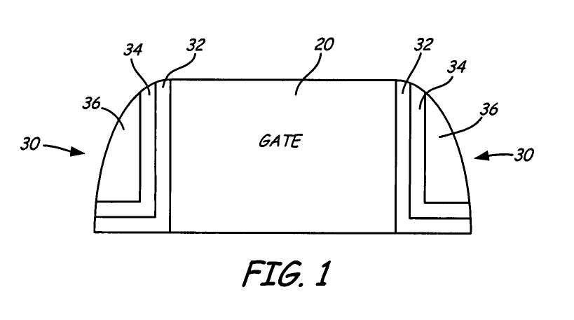

FIG. 1 shows an implementation of the present invention. Gate 20 is the gate of a MOSFET. Gate 20 is bordered by spacer 30. Spacer 30 is composed of three spacer layers 32, 34 and 36. Typically, layers 32 and 36 are composed of silicon oxide and layer 34 is made of silicon nitride. However, other materials may also be used.

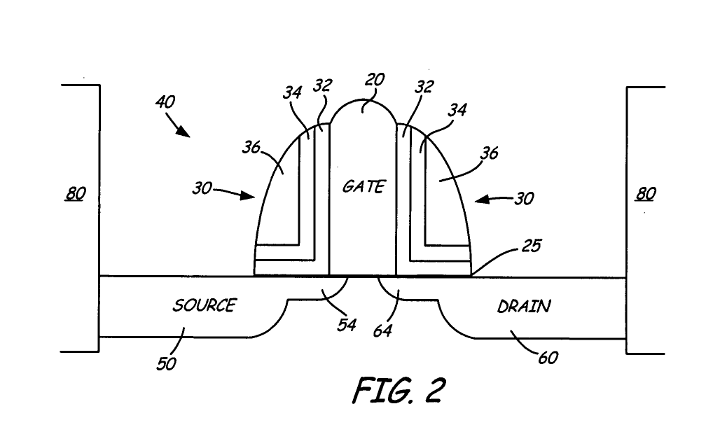

FIG. 2 shows the implementation of the present invention in the context of MOSFET 40. MOSFET 40 includes gate 20, gate oxide 25, source 50 and drain 60. Source 50 includes lightly doped region 54 and drain 60 includes lightly doped region 64. A multi-layered spacer 30 is located on both sides of gate 20 and above the lightly doped regions 54 and 64 of the source 50 and drain 60. MOSFET 40 is built upon body 70 and is typically bounded on both sides by field oxide 80. Spacer 30 includes layers 32, 34 and 36. Typically, layers 32 and 36 are composed of silicon oxide and layer 34 is made of silicon nitride. However, other materials may also be used.

MOSFET 40 is fabricated using a self-aligning process. Gate oxide 25 is first grown over body 70. Gate 20 is then deposited on body 70. Gate 20 is typically made of doped polysilicon. Next, lightly doped regions 54 and 64 are implanted. Spacer 30 is formed next in the process. Spacer 30 is formed by depositing three layers of material on the surface of MOSFET 40 and then anisotropically etching the three layers for form the proper shape. For example, layer 32 is deposited first. Then, layer 34 is deposited on top of layer 32 and layer 36 is deposited on top of layer 34. After layer 36 has been deposited, the three layers are anisotropically etched into the desired shape of spacer 30.

After spacer 30 is etched, a second implant with higher doping concentrations takes place. Gate 20 and spacer 30 protect the region of substrate 70 beneath them, resulting in source 50 having a more lightly doped region 54 under spacer 30 and drain 60 having a more lightly doped region 64 under spacer 30.

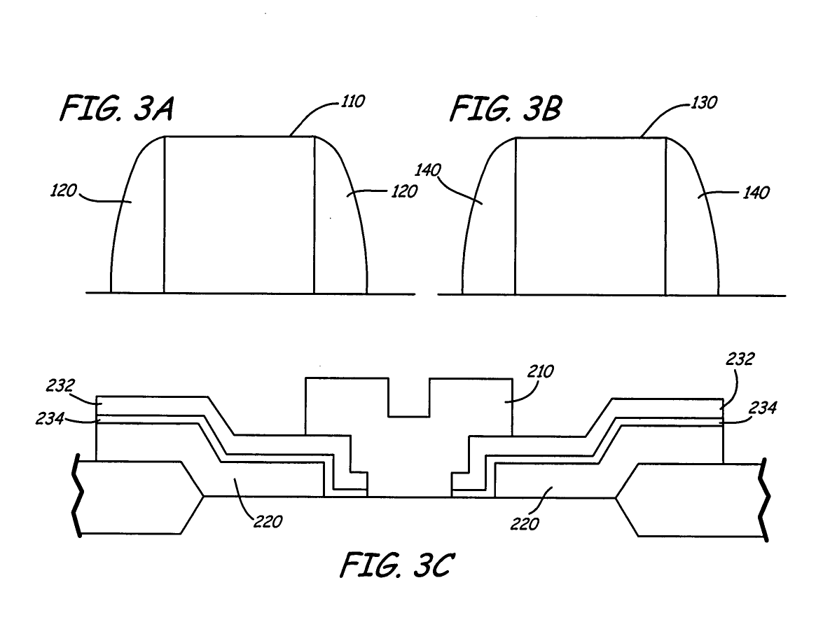

FIG. 3A and FIG. 3B show the prior art for purposes of comparison. FIG. 3A shows gate 110 of a MOSFET bounded on either side by oxide spacer 120. Similarly, FIG. 3B shows gate 130 bounded on either side by nitride spacer 140. Neither of these prior art devices have the multi-layered spacer of the invention.

FIG. 3C shows bipolar junction transistor with emitter 210 and base 220. Emitter 210 and base 220 are separated by double-layered spacer 230, which includes nitride layer 232 and oxide layer 234.

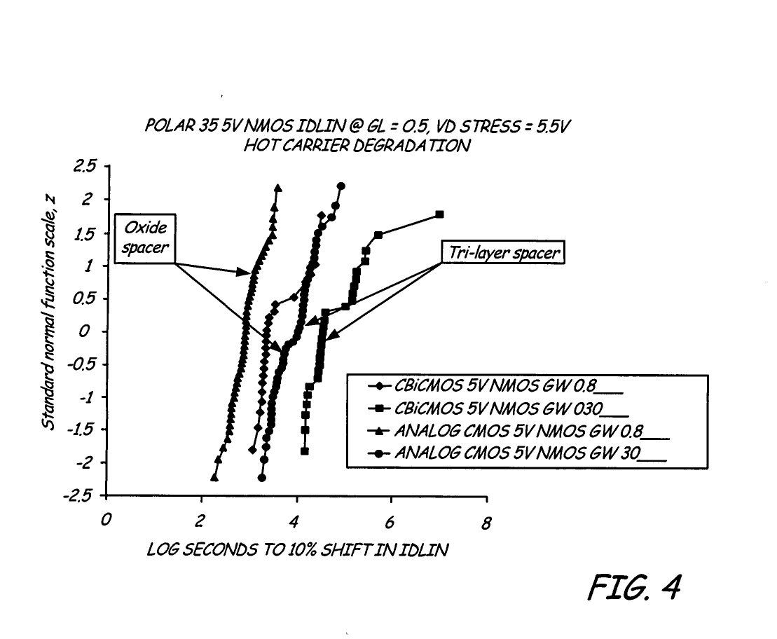

The configuration shown in FIG. 2 demonstrates improved performance over the prior art. FIG. 4 is a graph comparing the hot carrier degradation of MOSFETs containing a prior art oxide spacer with the hot carrier degradation of MOSFETs containing the multi-layered spacer of the invention. The graph shows the increased amount of time it takes MOSFETs utilizing the multi-layered spacer of the invention to reach a 10% shift in linear drive current (IDlin) under hot carrier induced degradation conditions. The IDlin in FIG. 4 is the MOSFET drain current measured when Vsource=Vbody=0V, Vgate=5.5V and Vdrain=0.1V. The x-axis of the graph in FIG. 4 represents time on a logarithmic scale, so “0” on the scale represent 10⁰ seconds, “1” represents 10¹ seconds, “2” represents 10² seconds, etc. The y-axis of the graph in FIG. 4 represents the “Standard normal function scale, z”, a common way to plot statistical data. Essentially, “z” represents how many standard deviations from the mean a particular data point would be, assuming a normal (bell-shaped) distribution given the data point's rank within the data set and the total number of data points in the data set.

However, as shown in the Table 1 below, other electrical parameters are very similar between a MOSFET with a prior art oxide spacer and a MOSFET with the multi-layered spacer of the invention.

TABLE 1

| Test | | Oxide | Oxide | Layered | Layered | | | | |
|---|---|---|---|---|---|---|---|---|---|
| name | Description | Mean | SDev | Mean | SDev | % Diff. | LimitLo | LimitHi | Units |
| 720N5SWDS | NMOS array | 8.949 | 0.168 | 8.930 | 0.239 | 0.2 | 8 | 25 | Volts |
| | drain-to-source | | | | | | | | |
| | breakdown | | | | | | | | |
| | voltage | | | | | | | | |
| 720N5SWIDS | NMOS array | 3.482 | 3.353 | 4.468 | 7.428 | 28.3 | −1000 | 460 | nA |
| | drain leakage | | | | | | | | |
| | current | | | | | | | | |
| 720P5SWDS | PMOS array | 7.729 | 0.068 | 7.884 | 0.143 | 2.0 | 8 | 12 | Volts |
| | drain-to-source | | | | | | | | |
| | breakdown | | | | | | | | |
| | voltage | | | | | | | | |
| 720P5SWIDS | PMOS array | 30.064 | 18.803 | 35.022 | 20.274 | 16.5 | −1000 | 230 | nA |
| | drain | | | | | | | | |
| | leakage current | | | | | | | | |
| N5SWDS | Single NMOS | 9.510 | 0.147 | 9.560 | 0.280 | 0.5 | 8 | 20 | Volts |
| | drain-to-source | | | | | | | | |
| | breakdown | | | | | | | | |
| | voltage | | | | | | | | |
| N5SWGMLIN | Single NMOS | 414.955 | 18.712 | 405.265 | 16.137 | −2.3 | 318 | 618 | uS/um |
| | current gain | | | | | | | | |
| N5SWIDSAT | Single NMOS | 531.153 | 14.614 | 524.432 | 14.632 | −1.3 | 490 | 670 | uA/um |
| | maximum drive | | | | | | | | |
| | current | | | | | | | | |
| N5SWIDSS | Single NMOS | 0.171 | 0.066 | 0.199 | 0.065 | 16.5 | −0.04 | 0.3 | nA |
| | drain leakage | | | | | | | | |
| | current | | | | | | | | |
| N5SWISUB | Single NMOS | 5.472 | 0.315 | 5.181 | 0.286 | −5.3 | 3.5 | 8.8 | uA/um |
| | maximum body | | | | | | | | |
| | current | | | | | | | | |
| N5SWVSUB | Single NMOS | 2.033 | 0.033 | 1.988 | 0.048 | −2.2 | 1 | 3 | Volts |
| | gate voltage that | | | | | | | | |
| | produces | | | | | | | | |
| | N5SWISUB | | | | | | | | |
| N5SWVT | Single NMOS | 778.7 | 17.5 | 779.5 | 34.6 | 0.1 | 650 | 650 | mV |
| | threshold voltage | | | | | | | | |
| P5SWDS | Single PMOS | 8.023 | 0.126 | 8.320 | 0.147 | 3.7 | 7.5 | 15 | Volts |
| | drain-to-source | | | | | | | | |
| | breakdown | | | | | | | | |
| | voltage | | | | | | | | |
| P5SWGMLIN | Single PMOS | 136.520 | 4.399 | 135.202 | 4.448 | −1.0 | 102 | 188 | uS/um |
| | current gain | | | | | | | | |
| P5SWIDSAT | Single PMOS | 292.863 | 9.757 | 294.241 | 9.775 | 0.5 | 210 | 400 | uA/um |
| | maximum drive | | | | | | | | |
| | current | | | | | | | | |
| P5SWIDSS | Single PMOS | 0.028 | 0.045 | 0.058 | 0.021 | 106.2 | −1.25 | 0.3 | nA |
| | drain leakage | | | | | | | | |
| | current | | | | | | | | |
| P5SWISUB | Single PMOS | 0.122 | 0.014 | 0.143 | 0.017 | 17.0 | 0.02 | 0.24 | uA/um |
| | maximum body | | | | | | | | |
| | current | | | | | | | | |
| P5SWVSUB | Single PMOS | 1.951 | 0.017 | 1.927 | 0.025 | −1.2 | 1 | 3 | Volts |
| | gate voltage that | | | | | | | | |
| | produces | | | | | | | | |
| | N5SWISUB | | | | | | | | |
| P5SWVT | Single PMOS | 750.0 | 22.1 | 733.6 | 19.1 | −2.2 | 600 | 900 | mV |
| | threshold voltage | | | | | | | | |

In addition to reduced hot carrier degradation, the invention demonstrates improved end-point detection during spacer etching. As noted, after deposition of the spacer layers 32, 34 and 36, the layers must be etched in order to create spacer 30. This is not unique to the invention. Even if a single layered spacer is used, the single layer must be etched to create the spacer. However, when etching the spacer layer or layers, it is desirable to remove as much of the spacer layer as possible in the desired location, without etching away any of the doped substrate below it. Thus, it is important to be able to accurately detect the end-point of the spacer layer, so that additional material, such as the substrate, is not etched away. At the same time, it is desirable to not stop etching too soon, since this will leave spacer layer material in places on the circuit where it is not wanted.

The multi-layered spacer of the invention improves etching end-point detection. When etching the surface of an integrated circuit, the material being etched away can be detected by sensors. If a single material is used for the spacer layer (silicon oxide, for instance), then the etched material will all be silicon oxide. Sensing that silicon oxide is being removed will not be helpful until all of the oxide is etched away, and the underlying substrate is being removed. However, if a multi-layered spacer material is used, then different materials will be detected as the etching progresses. For example, if the spacer layers are made of oxide-nitride-oxide layers, then during etching the first material being etched away will be oxide. At some point, nitride will be detected as being removed, so it will be known that the second layer is now being etched. Similarly, it can be detected when nitride etching stops and oxide is again being removed. At this point, it will be known that the final layer of spacer material is being removed. In this way, it is much easier to estimate when all of the spacer material has been removed and the substrate has been reached.

Of course, MOSFETs are not created individually. Generally, thousands of MOSFETs are fabricated together in integrated circuits. Building integrated circuits requires many steps in which layers are added to the circuit or layers are modified by etching, diffusing, implanting, oxidizing, depositing, etc. Thus, each additional step increases the complexity and expense of building the integrated circuit, and minimizing the number of steps is an important criterion in circuit design.

Another advantage of the invention is that is easy to integrate application of anti-reflective coatings to integrated circuits utilizing the invention. Photodiodes and other optical applications benefit from anti-reflective coatings that maximize the signal by reducing losses of light from reflection. Use of a dual layer anti-reflective coating instead of a single layer anti-reflective coating can further reduce reflection loss. Using silicon nitride as the second layer of a double layer anti-reflective coating has the additional benefit of protecting the photodiode from humidity and contaminants.

In building spacer 30, layer 32 is deposited first by low-pressure chemical vapor deposition or some other deposition process. Next, layer 34 is deposited on top of layer 32, and layer 36 is deposited on top of layer 34. Portions of layers 32, 34 and 36 are etched away to form spacer 30. However, layers 32 and 34 form a dual-layer anti-reflective coating. Thus, deposition of these layers serves the dual purpose of creating multi-layered spacer 30 with its reduced hot carrier degradation and etching-endpoint detection and creating a high quality anti-reflective coating over other areas of the integrated circuit.

The invention is a multi-layered spacer in a lightly-doped drain MOSFET. The multi-layered spacer exhibits reduced hot carrier degradation compared to a silicon dioxide spacer, resulting in a longer useful lifetime for the device. Other device parameters remain the same, so the device can be used in the same applications as traditional LDD MOSFETs containing single-layer spacers. In addition, the multi-layered spacer exhibits improved end-point detection when etching the spacer. Finally, the multi-layered spacer is easily incorporated into integrated circuit fabrication that includes application of anti-reflective coating.

Although the present invention has been described with reference to preferred embodiments, workers skilled in the art will recognize that changes may be made in form and detail without departing from the spirit and scope of the invention.

1. A spacer for a lightly-doped drain MOSFET comprising:
a first spacer layer adjacent to and in contact with a gate region and a lightly-doped region;
a second spacer layer adjacent to and in contact with the first layer;
a third spacer layer adjacent to and in contact with the second layer;

2. The spacer of claim 1 wherein the first spacer layer is comprised of an insulator.

3. The spacer of claim 2 wherein the first spacer layer is comprised of silicon oxide.

4. The spacer of claim 1 wherein the second spacer layer is comprised of an insulator.

5. The spacer of claim 4 wherein the second spacer layer is comprised of silicon nitride.

6. The spacer of claim 1 wherein the third spacer layer is comprised of an insulator.

7. The spacer of claim 6 wherein the third spacer layer is comprised of silicon oxide.

8. The spacer of claim 1 further comprising a multi-layer anti-reflective coating integral with the spacer layers.

9. A semiconductor device comprising:
a source region of a first conductivity type;
a drain region of a first conductivity type;
a channel region of a second conductivity type between the source region and drain region;
lightly-doped drain regions connecting the source region and drain region with the channel region;
a gate oxide overlying the channel and lightly-doped drain regions;
a polysilicon gate region aligned over the channel region;
an oxide layer interposed between the gate region and the channel region;
a spacer adjacent to the gate region and overlying the lightly-doped drain region, wherein the spacer is formed of first, second and third spacer layers.

10. The semiconductor device of claim 9 wherein the first spacer layer is comprised of an insulator.

11. The semiconductor device of claim 10 wherein the first spacer layer is comprised of silicon oxide.

12. The semiconductor device of claim 9 wherein the second spacer layer is comprised of an insulator.

13. The semiconductor device of claim 12 wherein the second spacer layer is comprised of silicon nitride.

14. The semiconductor device of claim 9 wherein the third spacer layer is comprised of an insulator.

15. The semiconductor device of claim 14 wherein the third spacer layer is comprised of silicon oxide.

16. The semiconductor device of claim 9 further comprising a multi-layer anti-reflective coating integral with the spacer layers.

17. A method for fabricating lightly-doped drain metal oxide semiconductor field effect transistors, the method comprising:
growing a gate oxide on a semiconductor body;
forming a polysilicon gate region on the gate oxide;
implanting a low-concentration dopant into the body around the gate region;
depositing a first spacer layer on the gate region and gate oxide;
depositing a second spacer layer on the first spacer layer;
depositing a third spacer layer on the second spacer layer;
etching the first, second and third spacer layers to form a spacer; and
implanting a high-concentration dopant into the substrate around the spacer to form a source region and a drain region.

18. The semiconductor device of claim 17 wherein the first spacer layer is comprised of an insulator.

19. The semiconductor device of claim 18 wherein the first spacer layer is comprised of silicon oxide.

20. The semiconductor device of claim 17 wherein the second spacer layer is comprised of an insulator.

21. The semiconductor device of claim 20 wherein the second spacer layer is comprised of silicon nitride.

22. The semiconductor device of claim 17 wherein the third spacer layer is comprised of an insulator.

23. The semiconductor device of claim 22 wherein the third spacer layer is comprised of silicon oxide.
